(19) United States
(12) Patent Application Publication
(10) Pub. No.: US 2020/0411408 A1
(43) Pub. Date: Dec. 31, 2020

(54) DEFLECTED-PILLAR COMPOSITE COMPLIANT ELONGATED MICRO-STRUCTURE THERMAL INTERFACE MATERIALS

(71) Applicant: Intel Corporation, Santa Clara, CA (US)

(72) Inventors: Joe Walczyk, Tigard, OR (US); Pooya Tadayon, Hillsboro, OR (US); Michael Rutigliano, Chandler, AZ (US); Chandra M. Jha, Chandler, AZ (US); Zhimin Wan, Chandler, AZ (US)

(21) Appl. No.: 16/454,393

(22) Filed: Jun. 27, 2019

(51) Int. Cl. H01L 23/373; H01L 25/065; H01L 25/18; H01L 23/367; H01L 23/427; F28F 13/00

(52) U.S. Cl. CPC H01L 23/3733; H01L 25/0655; H01L 25/18; F28F 2013/006; H01L 23/427; F28F 13/00; F28F 2013/005; H01L 23/3675

(57) ABSTRACT

Disclosed embodiments include composite compliant pillars in a micro-structure array that extend at a non-orthogonal angle from a heat-sink base. The array is deployed against an integrated-circuit device package to deflect the composite compliant pillar array under conditions where heat-transfer performance is agnostic to dynamic non-planarity of the integrated-circuit device package.

### FIELD

This disclosure relates to heat management of integrated-circuit devices for both test and field use.

### BACKGROUND

Integrated-circuit chip miniaturization experiences power density increase and chip-size decrease. Die and package warpage affect chip performance.

### BRIEF DESCRIPTION OF THE DRAWINGS

Disclosed embodiments are illustrated by way of example, and not by way of limitation, in the figures of the accompanying drawings where like reference numerals may refer to similar elements, in which:

FIG. 1A is a cross-section elevation of a composite compliant pillar thermal-interface material array, with micro-structure pillars in an array during assembly to an integrated-circuit die according to an embodiment;

FIG. 1B is a cross-section elevation of the composite compliant micro-structure array depicted in FIG. 1A after further assembly according to an embodiment;

FIG. 2A is a cross-section elevation of an integrated-circuit 201 that is contacted by a deflected pillar composite compliant micro-structure arrays according to several embodiments;

FIG. 2B is a cross-section elevation of an integrated-circuit apparatus that is contacted by a deflected pillar composite compliant micro-structure arrays according to several embodiments:

FIG. 2C is a cross-section elevation of an integrated-circuit apparatus that is contacted by deflected pillar composite compliant micro-structure arrays for high-bandwidth memory dice, that are packaged with integrated-circuit dice such as pair of processors, for example a central-processing unit and a graphics-processing unit according to several embodiments;

FIG. 3A is a cross-section elevation of a device under thermal test according to an embodiment;

FIG. 3B is a cross-section elevation of a device under thermal test according to an embodiment:

FIG. 4 is a computer-rendered digital photograph of a composite compliant micro-structure array according an embodiment;

FIG. 5 is a computer-rendered digital photograph of a composite compliant micro-structure array as it extends from a heat-sink base according to an embodiment:

FIG. 6A is a cross-section elevation of an integrated-circuit apparatus that is contacted by a deflected-pillar composite compliant micro-structure array under convex warping operational conditions according to several embodiments

FIG. 6B is a cross-section elevation of an integrated-circuit apparatus that is contacted by a deflected-pillar composite compliant micro-structure array under concave warping operational conditions according to several embodiments;

FIG. 7A is an extraction elevation of a compliant pillar that is deployed between a heat-sink base and an integrated-circuit die according to an embodiment;

FIG. 7B is a digitized computer rendering of a compliant pillar that contacts a solder on the backside surface of an integrated-circuit die according to an embodiment;

FIG. 7C is an extraction elevation of a compliant pillar that is deployed between a heat-sink base and an integrated-circuit die according to an embodiment;

FIG. 8 is a cross-section elevation extraction of an integrated-circuit device package according to several embodiments;

FIG. 9 illustrates cross-section form factors of several compliant pillar embodiments;

FIG. 10 is side elevation of compliant pillars according to several embodiments:

FIG. 11 is a perspective elevation of a composite compliant micro-structure array in an integrated-circuit package where a micro-structure buckling beam is configured in an array between a heat-sink base and an integrated-circuit die according to an embodiment:

FIG. 11A is a perspective elevation detail of the micro-structure buckling beam depicted in FIG. 11 according to an embodiment;

FIG. 11B is a perspective elevation of a composite compliant micro-structure array in an integrated-circuit package, where an energy-storage device that uses a cold block and a heater, are assembled to a composite compliant pillar micro-structure buckling beam array according to an embodiment;

FIG. 12 is a process flow diagram according to several embodiments; and

FIG. 13 is included to show an example of a higher-level device application for the disclosed embodiments.

### DETAILED DESCRIPTION

Disclosed embodiments include composite compliant micro-structure thermal interface material configurations to allow die and package warpage with continuous heat-transfer from the integrated circuits on the package. Several embodiments include composite, compliant pillar thermal interface materials (CCP TIMs) that by the pillar structure, angle, array density and compliance, among other qualities, spread heat transfer and lower heat-transfer resistance due to continuous performance under expected warpage of a given article such as an integrated-circuit die on a package.

The CCP TIM arrays include angled pillars that deviate from the orthogonal with relation to the base from which they extend, such as a 40° angle from the plane of the heat-sink base. In an embodiment, the angle is in a range from 20 to 65°. In an embodiment, the CCP TIM arrays can include an array of compliant elongated micro-structure pillars that have a pillar height in a range from 100 micrometer (μm) to 500 μm, a pillar cross section of 10 to 60 μm, and a bending compliance in a range from 10 to 50 μm. In an embodiment, the CCP TIM arrays can include an array of compliant elongated micro-structure pillars that have a pillar height in a range from 200 micrometer (μm) to 350 μm, a pillar cross section of 20 to 40 μm, and a bending compliance in a range from 20 to 30 μm. In an embodiment, the CC pillars have a cross-section in a range from 10 to 50 μm. In an embodiment, the CC pillars have a cross-section in a range from 20 to 30 μm.

Fabrication of compliant micro structure pillars includes electroplating deposition of metallic pillars at angles that depart from orthogonal to a base. In an embodiment, a filler is deployed among compliant pillars to facilitate heat transfer between a heat-generating integrated-circuit die and the compliant pillars and a heat sink such as a heat spreader. In an embodiment, an array of compliant micro structure pillars are agnostic to both convex and concave deflection of a package substrate, or the integrated-circuit die on the package substrate, with respect to heat extraction through the composite compliant-pillar TIM array.

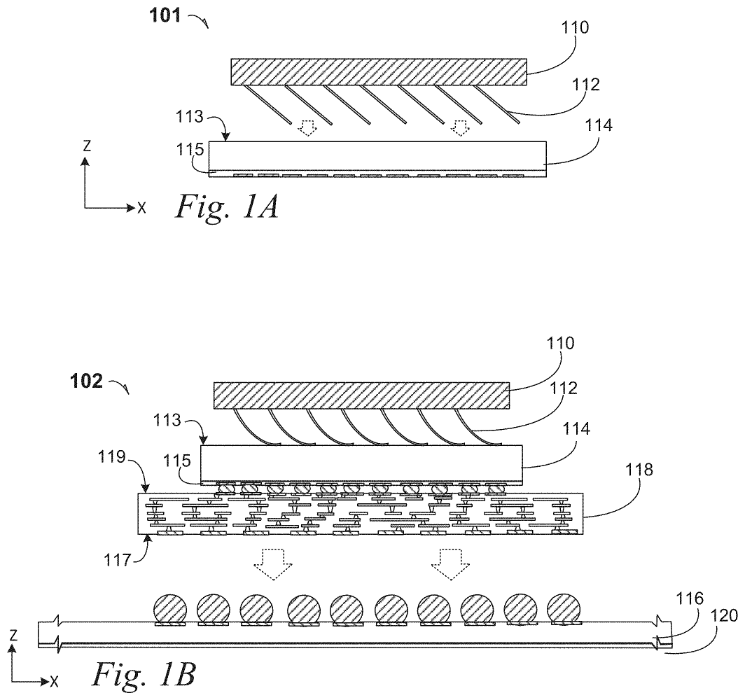

FIG. 1A is a cross-section elevation 101 of a composite compliant pillar thermal-interface material array, with micro-structure pillars 112 in an array during assembly to an integrated-circuit die 114 according to an embodiment. A heat-sink base 110 includes a composite compliant pillar array of micro-structure pillars 112, one angled pillar of which is enumerated with item 112, that extends from the heat-sink base 110 at an angle to the orthogonal, such as a 40° angle to the X-Y plane of the heat-sink base 110. In an embodiment, the angle is in a range from 30 to 50°.

In an embodiment, an integrated-circuit die 114 includes active devices and metallization 115 and a backside surface 113. The heat-sink base 110 and the composite compliant micro-structure array 112 are being brought into contact with the backside surface 113, as indicated by directional arrows.

FIG. 1B is a cross-section elevation 101 of the composite compliant micro-structure array 112 depicted in FIG. 1A after further assembly according to an embodiment. The composite compliant micro-structure array 112′ has been brought into contact with the integrated-circuit die 114 according to an embodiment. The composite compliant micro-structure array 112′ has contacted the backside surface 113, and at least the distal ends of each compliant micro-structure 112′ has deflected, such that each pillar-like structure 112′ contacts the backside surface 113, whether the backside surface 113 is substantially planar or whether the backside surface 113 may have a detectible non-planar form. Each pillar 112′ is under a compressive load exhibited by the deflection upon the backside surface 113.

In an embodiment, the integrated-circuit die 114 is seated on an integrated-circuit package substrate 118, where the active devices and metallization 115 of the IC die 114 are coupled to a die side 119, and a land side 117 is being brought toward a board 116, such as a mother board 116.

In an embodiment, an external shell 120 is an integral part of the board 116 and the integral shell 120 acts as an insulative and structural protection for the apparatus that includes the deflected pillar compliant micro-structure 112′, the integrated-circuit die 114, and the integrated-circuit package substrate 118. In an embodiment, the board 116 and shell 120 are part of a hand-held computing system. In an embodiment, the board 116 and shell 120 are part of a mobile computing system such as a drone.

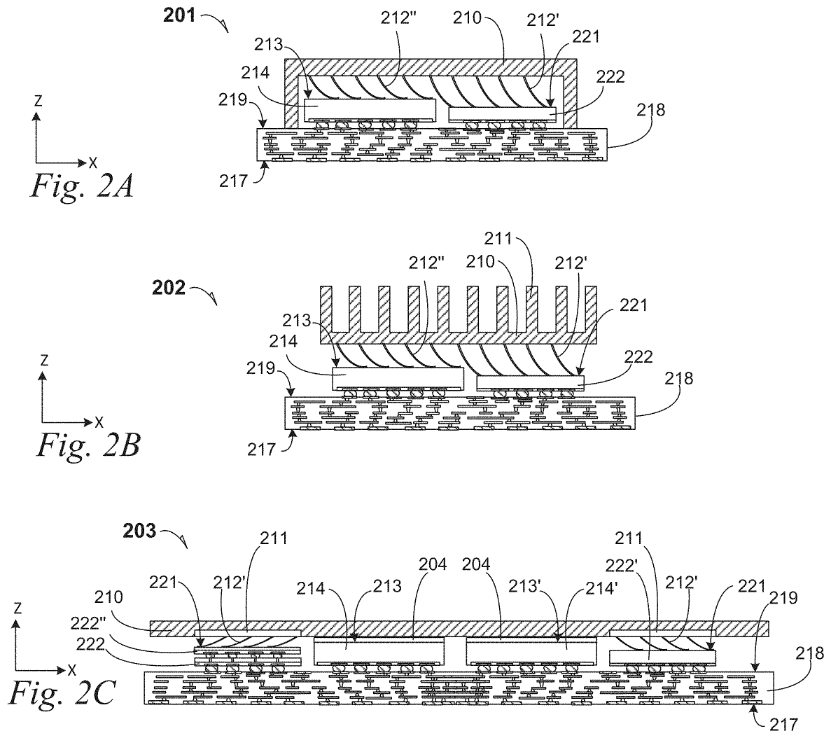

FIG. 2A is a cross-section elevation of an integrated-circuit apparatus 201 that is contacted by a deflected pillar composite compliant micro-structure arrays 212′ and 212″ according to several embodiments. In a multi-chip package, an assembly embodiment includes a heat-sink base 210 that is in the form factor of an integrated heat spreader (IHS) or “lid” that includes a composite compliant micro-structure array, one angled pillar of which is enumerated with item 212″, that extends from the heat-sink base 210 to a first integrated-circuit die 214 with a first height, and one angled pillar of which is enumerated with item 212′, that also extends from the heat-sink base 210 to a subsequent integrated-circuit die 222 with a subsequent height that is less than the first height. Before assembly, each of the compliant elongated micro-structures in the array, extend from the heat-sink base 210 at an angle to the orthogonal, such as a 40° angle to the X-Y plane of the heat-sink base 210.

In an embodiment, a first integrated-circuit die 214 includes active devices and metallization and a backside surface 213. Additionally, a subsequent integrated-circuit die 222 includes active devices and metallization and a backside surface 221. The heat-sink base 210 and the compliant micro-structure array 212′ and 212″ have being brought into contact with backside surfaces 213 and 221. Deflection of the composite compliant micro-structure array has differently deflected pillars 212′ and 212″ as each has contacted the respective backside surfaces 221 and 213, and at least the distal ends of each compliant micro-structure 212′ and 212″ has deflected, such that each pillar-like structure 212′ and 212″ contacts the respective backside surfaces 221 and 213, whether the backside surfaces are substantially planar or whether the backside surfaces may have a detectible non-planar form. Each pillar 212′ and 212″ is under a compressive load exhibited by the degree of deflection at the respective backside surfaces 221 and 213.

In an embodiment, the integrated-circuit dice 214 and 222 are part of an MCP where the dice 214 and 222 are seated on an integrated-circuit package substrate 218, where the active devices and metallization of the IC dice 214 and 222 are coupled to a die side 219. A land side 217 can be assembled to a board such as the board 116 depicted in FIG. 1B by way of non-limiting example.

FIG. 2B is a cross-section elevation of an integrated-circuit apparatus 202 that is contacted by a deflected pillar composite compliant micro-structure arrays 212′ and 212″ according to several embodiments. In a multi-chip package, an assembly embodiment includes a heat-sink base 210 that includes cooling fins 211, includes a composite compliant micro-structure array, one angled pillar of which is enumerated with item 212″, that extends from the heat-sink base 210, and one angled pillar of which is enumerated with item 212′, that also extends from the heat-sink base 210. Before assembly, each of the compliant elongated micro-structures in the array, extend from the heat-sink base 210 at an angle to the orthogonal, such as a 40° angle to the X-Y plane of the heat-sink base 210.

In an embodiment, a first integrated-circuit die 214 includes active devices and metallization and a backside surface 213. Additionally, a subsequent integrated-circuit die 222 includes active devices and metallization and a backside surface 221. The heat-sink base 210 and the compliant micro-structure array 212′ and 212″ have being brought into contact with backside surfaces 213 and 221. Deflection of the composite compliant micro-structure array has differently deflected pillars 212′ and 212″ as each has contacted the respective backside surfaces 221 and 213, and at least the distal ends of each compliant micro-structure 212′ and 212″ has deflected, such that each pillar-like structure 212′ and 212″ contacts the respective backside surfaces 221 and 213, whether the backside surfaces are substantially planar or whether the backside surfaces may have a detectible non-planar form. Each pillar 212′ and 212″ is under a compressive load exhibited by the degree of deflection at the respective backside surfaces 221 and 213.

In an embodiment, the integrated-circuit dice 214 and 222 are part of an MCP where the dice 214 and 222 are seated on an integrated-circuit package substrate 218, where the active devices and metallization of the IC dice 214 and 222 are coupled to a die side 219. A land side 217 can be assembled to a board such as the board 116 depicted in FIG. 1B by way of non-limiting example.

Not illustrated are hold-down devices such as a bolt that holds the heat sink base 210 onto the die side 219 of the integrated-circuit package substrate 218.

FIG. 2C is a cross-section elevation of an integrated-circuit apparatus 203 that is contacted by deflected pillar composite compliant micro-structure arrays 212 for stacked dice 222 and 222″ and a single die 222′ that are packaged with direct-TIM dice 214 and 214′ according to an embodiment.

In an embodiment, high-bandwidth memory (HBM) dice 222 and 222″ (stacked on die 222) are packaged with integrated-circuit dice 214 such as pair of processors, for example a central-processing unit 214 and a graphics-processing unit 214′ according to several embodiments. In a multi-chip package, an assembly embodiment includes a heat-sink base 210 that encompasses heat pipes 211 for the stacked dice 222 and 222″, and thermal interface materials 204 that contact between the processors 214 and 214′ and the heat-sink base 210.

Whereas the processor integrated-circuit dice 214 and 214′ are bonded to the heat-sink base 210 by the TIMs 204, the stacked integrated-circuit dice 222 and 222″ are thermally coupled to the heat-sink base 210 by CCP TIM arrays 212′. During flexing and bending of such structures as the integrated-circuit package substrate 218, or even the processor dice 214 and 214′, heat transfer between the stacked dice 222 and 222″ is maintained where the CCP TIM arrays 212′ are agnostic to changing distances between die backsides 221 and the heat pipes 211.

In an embodiment, a chipset includes a processor die 214, a platform-controller hub die 214′, a stack of memory dice 222 and 222″ (adjacent the processor die 214) and a baseband processor die 222′ (adjacent the MCH die 214′). Other chipsets may be configured, including CPU and GPU dice 214 and 214′ with stacked dice 222 and 222″ as illustrated, and in a different X-Y plane, an MCH die (behind die 214) with a second CPU die (behind CPU die 214′), a memory die 222 (adjacent the processor die 214) and a baseband processor die 222 (adjacent the MCH die 214′).

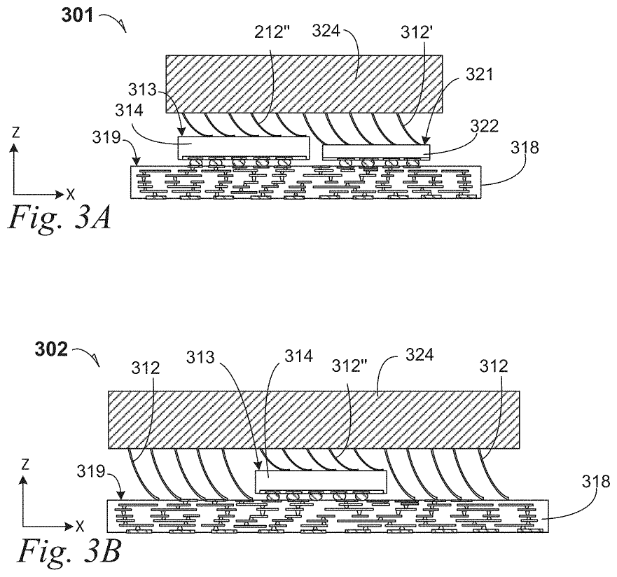

FIG. 3A is a cross-section elevation of a device under thermal test 301 according to an embodiment. The devices under test (DUTs) 314 and 322 are contacted by deflected pillar composite compliant micro-structure arrays 312′ and 312″ while a thermal head 324 is both pressing upon the DUTs 314 and 322, and imposing a thermal load on the DUTs according to several embodiments.

In an embodiment, the first integrated-circuit DUT 214 includes active devices and metallization and a backside surface 213. Additionally, the subsequent integrated-circuit DUT 222 includes active devices and metallization and a backside surface 321. The thermal head 324 and the compliant micro-structure array 312′ and 312″ have been brought into contact with backside surfaces 313 and 321. Deflection of the composite compliant micro-structure array has differently deflected pillars 312′ and 312″ as each has contacted the respective backside surfaces 321 and 313, and at least the distal ends of each compliant micro-structure 312′ and 312″ has deflected, such that each pillar-like structure 312′ and 312″ contacts the respective backside surfaces 321 and 313, whether the backside surfaces are substantially planar or whether the backside surfaces may have a detectible non-planar form. Each pillar 312′ and 312″ is under a compressive load exhibited by the degree of deflection.

FIG. 3B is a cross-section elevation of a device under thermal test 302 according to an embodiment. The device under test 314 is smaller than a thermal head 324, and the DUT 314 is contacted by deflected pillar composite compliant micro-structure arrays 312″ while non-contacting pillars 312 do not contact the DUT 314, although the non-contacting pillars 312, may contact a die side 319 of an integrated-circuit package substrate 318, while the thermal head 324 is both pressing upon the DUT, and imposing a thermal load on the DUT according an embodiment.

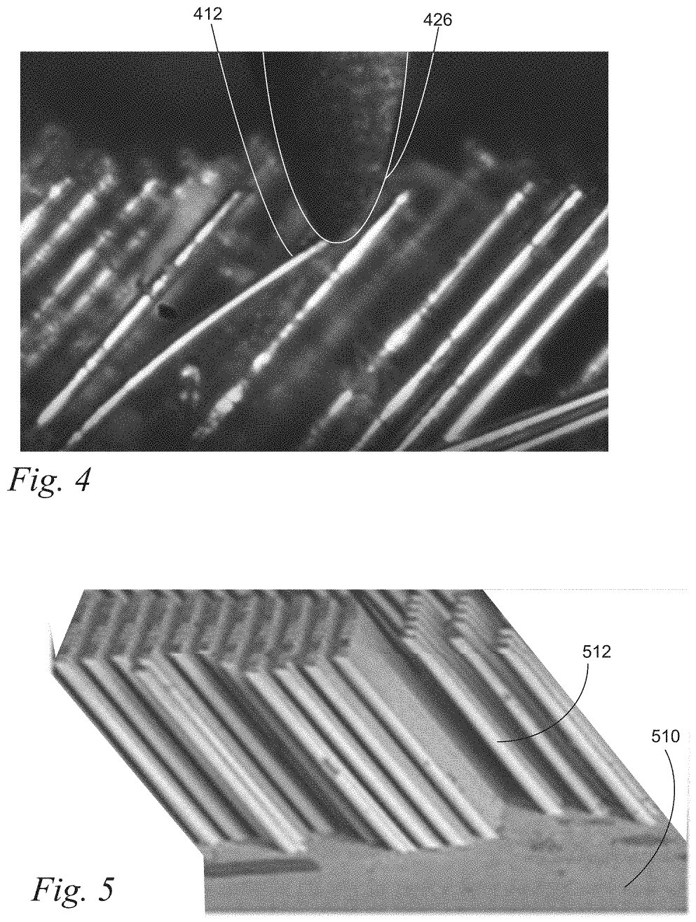

FIG. 4 is a computer-rendered digital photograph of a composite compliant micro-structure array according an embodiment. A probe 426 in approximate outline, is contacting and deflecting a single compliant pillar 412, while other compliant pillars are not deflecting, but they are at repose at a given angle that deviates from the orthogonal.

FIG. 5 is a computer-rendered digital photograph of a composite compliant micro-structure array as it extends from a heat-sink base according to an embodiment. The heat-sink base 510 includes a metallic material such as electronics-grade copper, and the composite array of compliant micro-structure pillars 512 extend from the heat-sink base 510 at an angle that deviates from the orthogonal.

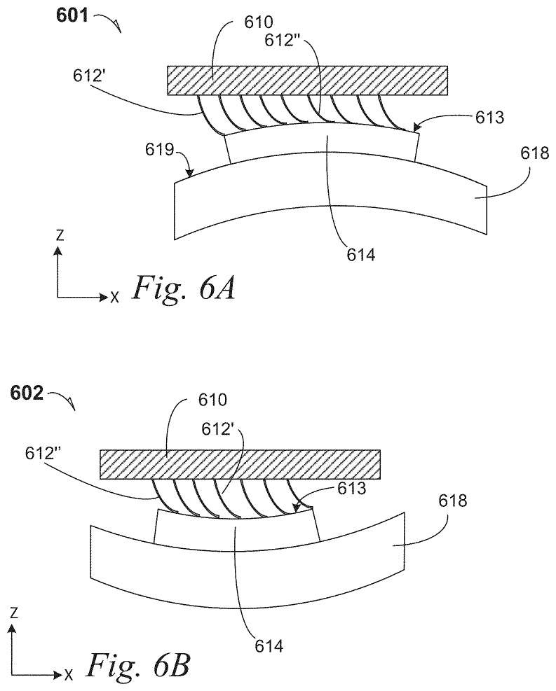

FIG. 6A is a cross-section elevation of an integrated-circuit apparatus 601 that is contacted by a deflected-pillar composite compliant micro-structure array 612′ and 612″ under convex warping operational conditions according to several embodiments.

An assembly embodiment includes a heat-sink base 610 that includes a composite compliant micro-structure array, the individual pillars of which are under varying degrees of deflection because of the warping and the specific contact locations of each pillar upon a backside surface of an integrated-circuit die 614. At minimum deflection near the edges of the integrated-circuit die 614, a deflected compliant pillar 612′ contacts the backside surface 613 of the integrated-circuit die 614. At maximum deflection near the middle of the integrated-circuit die 614, a deflected compliant pillar 612″ contacts the backside surface 613 of the integrated-circuit die 614. Each pillar 612′ and 612″ is under a compressive load as exhibited by the degree of deflection at the backside surface 613.

FIG. 6B is a cross-section elevation of an integrated-circuit apparatus 602 that is contacted by a deflected-pillar composite compliant micro-structure array 612′ and 612″ under concave warping operational conditions according to several embodiments. An assembly embodiment includes a heat-sink base 610 that includes a deflected-pillar composite compliant micro-structure array, the individual pillars of which are under varying degrees of deflection because of the warping and the specific contact locations of each pillar upon a backside surface of an integrated-circuit die 614. At minimum deflection near the center of the integrated-circuit die 614, a deflected compliant pillar 612′ contacts a backside surface 613 of the integrated-circuit die 614. At maximum deflection near the edges of the integrated of the integrated-circuit die 614, a deflected compliant pillar 612″ contacts the backside surface 613 of the integrated-circuit die 614. Each pillar 612′ and 612″ is under a compressive load exhibited by the degree of deflection.

It may now be understood that both convex and concave flexing of a given integrated-circuit die, may be continuously contacted by a composite compliant micro-structure array such as the several individual pillars 612′ and 612″ during field use of the integrated-circuit die 614.

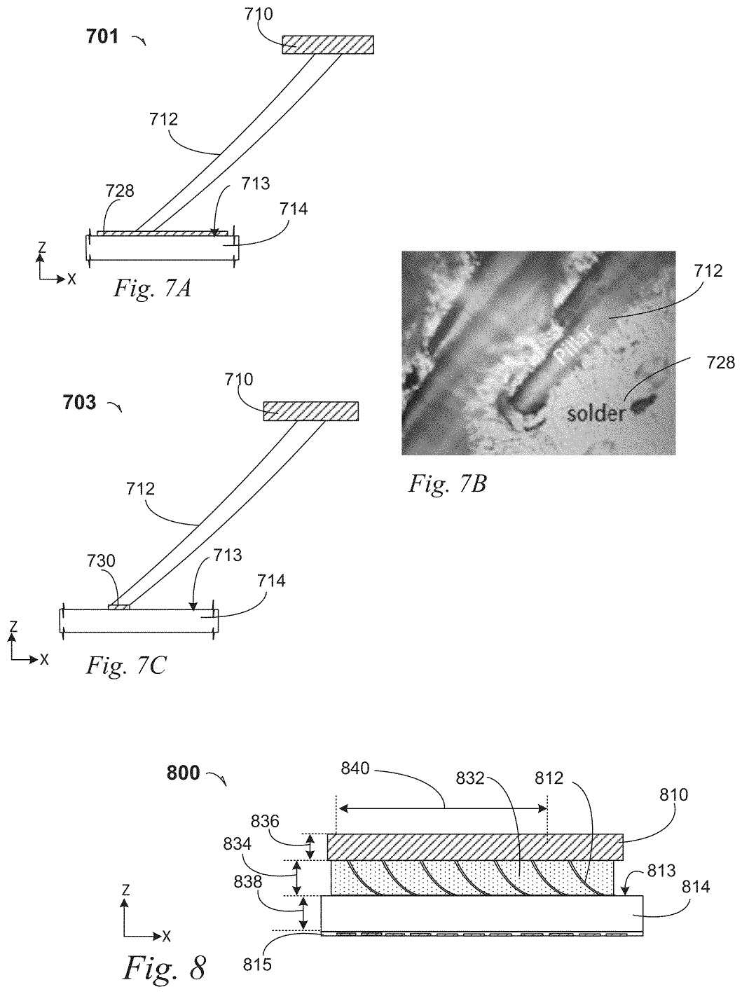

FIG. 7A is an extraction elevation of a compliant pillar 712 that is deployed between a heat-sink base 710 and an integrated-circuit die 714 according to an embodiment. A compliant pillar 712 such as an electronics-grade copper that has been formed on the heat-sink base 710, such as by plating into a pillar-form-factor negative space in a patterned mask. In an embodiment, each compliant pillar 712 is made from a graphene material that provides both heat-transfer ability and flexibility.

In an embodiment, a 0.2 mm thick mask is formed on the heat-sink base 710 and patterned to form a negative space for a compliant pillar to be plated into the negative space. Thereafter, the mask is removed such as by a wet etch, and compliant pillar 712 extends from the heat-sink base 710 at an angle that is non-orthogonal to the general plane of the heat-sink base 710, such as about 40° on the acute-angle presentation of the compliant pillar 712 from the heat-sink base.

After formation of a compliant micro-structure array that includes the compliant pillar 712, the compliant pillar 712 is brought into contact with a backside surface 713 of the integrated-circuit die 714, where the backside surface 713 is covered with a pillar-wetting material 728 in a film form factor such as a solder. In an embodiment, the backside surface includes a die-backside metallurgy (DBM) and the pillar-wetting material 728, wets both the DBM and the pillar 712 where it deflects. In an embodiment, the pillar-wetting material 728 is an indium-containing alloy that usefully adheres to the die backside surface 713 and wets the distal end of the compliant pillar 712, to provide adhesive contact between the distal end of the compliant pillar 712 and the heat-sink base 710. In an embodiment, the solder 728 is a silver-containing material. In an embodiment, the solder 728 is a tin-containing material. In an embodiment, the solder 728 is a tin-indium-silver-containing material. In an embodiment, the solder 728 is a tin-indium-containing material. In an embodiment, the solder 728 is a lead-tin-containing material.

FIG. 7B is a digitized computer rendering of a compliant pillar 712 that contacts a solder 728 on the backside surface of an integrated-circuit die according to an embodiment. The distal end of the compliant pillar 712 has been wetted by the solder 728, and incidental pillar-climbing of the solder is depicted. The solder 728 facilitates the spreading of a lowered heat-transfer resistance, across the plane of a heat-sink base, and the pillar 712 is part of a solder-assisted CCP TIM array that is agnostic to a warping integrated-circuit die or the IC package substrate, or both.

FIG. 7C is an extraction elevation of a compliant pillar 712 that is deployed between a heat-sink base 710 and an integrated-circuit die 714 according to an embodiment. A compliant pillar 712 such as an electronics-grade copper that has been formed on the heat-sink base 710. In an embodiment, a 0.2 mm thick mask is formed on the heat-sink base 710, and patterned to form a negative space for a compliant pillar to be plated into the negative space. After plating the compliant pillar 712, a solder tip 730 is plated onto the distal end of the compliant pillar 712. Thereafter, the mask is removed such as by a wet etch, and compliant pillar 712 extends from the heat-sink base 710 at an angle that is non-orthogonal to the general plane of the heat-sink base 710, such as about 40° on the acute-angle presentation of the compliant pillar 712 from the heat-sink base.

After formation of a composite compliant micro-structure array that includes the compliant pillar 712, the compliant pillar 712 is brought into contact with a backside surface 713 of the integrated-circuit die 714, where the backside surface 713 is contacted by the solder tip 730. In an embodiment, the solder tip 730 is an indium-containing alloy that usefully adheres to the die backside surface 713 and wets the distal end of the compliant pillar 712, to provide adhesive contact between the distal end of the compliant pillar 712 and the heat-sink base 710. Other solder materials may be used. In an embodiment, the solder tip 730 is a silver-containing material. In an embodiment, the solder tip 730 is a tin-containing material. In an embodiment, the solder tip 730 is a tin-indium-silver-containing material. In an embodiment, the solder tip 730 is a tin-indium-containing material. In an embodiment, the solder tip 730 is a lead-tin-containing material.

FIG. 8 is a cross-section elevation extraction of an integrated-circuit device package 800 according to several embodiments. A heat-sink base 810 includes a composite compliant micro-structure array 812, one angled pillar of which is enumerated with item 812, that extends from the heat-sink base 110 at an angle to the orthogonal, such as a 40° angle to the X-Y plane of the heat-sink base 110.

In an embodiment, a heat-transfer filler 832 is deployed between a backside surface 813 of an integrated-circuit die 814, and a heat-sink base 810. In an embodiment, the heat-transfer filler 832 is a thermal grease. In an embodiment, the heat-transfer filler 832 is a polymer thermal-interface material (PTIM) that has a rigidity less than the sum of the pillars in the compliant micro-structure array 812. In an embodiment, the heat-transfer filler 832 is a thermal liquid such as a mineral oil. In an embodiment, the heat-transfer filler 832 is an inert gas such as nitrogen in a convective ambient. In an embodiment, the heat-transfer filler 832 is ambient air under a mechanically driven convective force.

In an embodiment, a heat-transfer distance 834 between the heat-sink base 810 and the integrated-circuit die 814 is in a range from 0.1 millimeter (mm) to 0.3 mm. In an embodiment, the distance 834 is in a range from 0.2 mm to 0.35 mm. In an embodiment, the heat-sink base 810 has a thickness between 1.0 mm and 2 mm. In an embodiment, the heat-sink base 810 has a thickness 836 of 1.5 mm. In an embodiment, the integrated-circuit die 814 has a thickness 838 in a range from 0.5 mm and 1.0 mm. In an embodiment, the integrated-circuit die 814 has a thickness of 0.76 mm.

Spacing of individual compliant pillars 812 is about six pillars across a distance 840 in a range from 0.25 mm to 0.75 mm, where the individual pillars 812 have an average cross section in a range from 20 to 30 μm in a range. In an embodiment, spacing of individual compliant pillars 812 is about six pillars across a distance 840 of 0.5 mm.

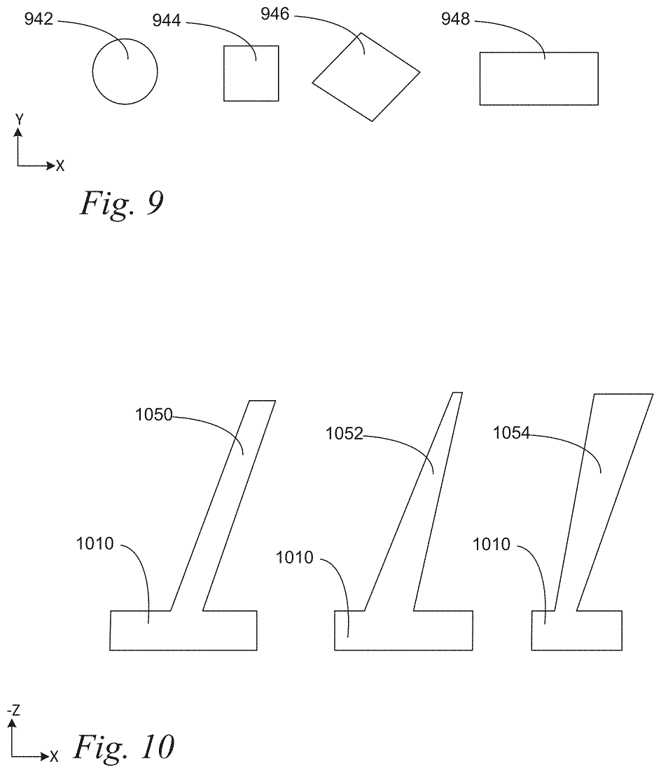

FIG. 9 illustrates cross-section form factors of several compliant pillar embodiments.

A circular cross-section pillar 942 is formed by plating through a mask, and it can be seen, after removal of the mask by exemplary embodiments illustrated in FIGS. 4 and 5. Bending of the circular pillar 942 is agnostic to the orientation of the pillar 942 as it bridges between a heat-sink base and an integrated-circuit backside surface. In an embodiment, the circular pillar 942 has an elliptical form factor.

In an embodiment, a square cross-section pillar 944 is formed by plating through a mask. Bending behavior of the square pillar 944 is dependent the orientation of the pillar 944 as it bridges between a heat-sink base and an integrated-circuit backside surface.

In an embodiment, an oblique-diamond cross-section pillar 946 is formed by plating through a mask. Bending behavior of the oblique-diamond pillar 946 is dependent the orientation of the pillar 944 and the degree of obliqueness in cross section, as it bridges between a heat-sink base and an integrated-circuit backside surface. In an embodiment, a rectangular cross-section pillar 948 is formed by plating through a mask. Bending behavior of the rectangular pillar 948 is dependent the orientation of the pillar 944 and the aspect ratio in cross section, as it bridges between a heat-sink base and an integrated-circuit backside surface. In an embodiment, the rectangular pillar 948 has an X-Y-Z width-length-height form factor of 1:4:9.

FIG. 10 is side elevation of compliant pillars according to several embodiments. In an embodiment, a straight pillar 1050 is formed by angled plating upon a heat-sink base 1010. The straight pillar 1050 may be any of the pillar form factors depicted in FIG. 9, where the cross section is uniform along the length. In an embodiment, a tapered pillar 1052 is formed by angled etching a progressively widening recess through a mask, followed by plating upon a heat-sink base 1010. In an embodiment, a reverse-tapered pillar 1054 is formed by angled etching a progressively narrowing recess through a mask, followed by plating upon a heat-sink base 1010.

In each embodiment, a solder layer or a solder tip, such as the layer 728 or the tip 730 depicted in respective FIGS. 7A and 7C, is applied at the distal end of the given pillar, 1050, 1052 and 1054, to further facilitate compliant lowered heat resistance and agnostic-to-warping structures under field conditions.

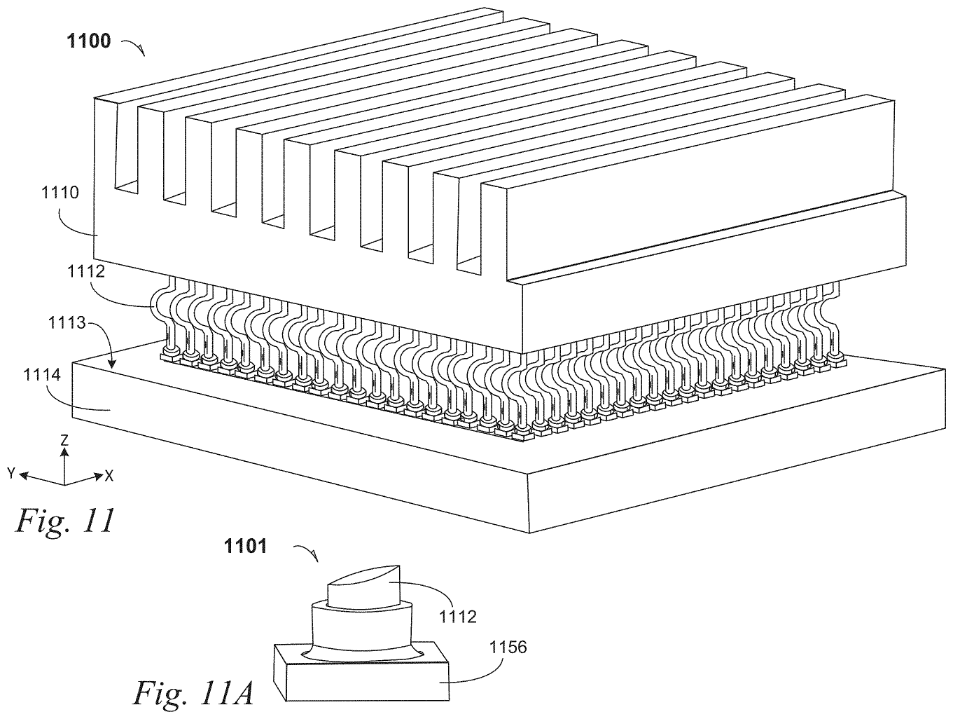

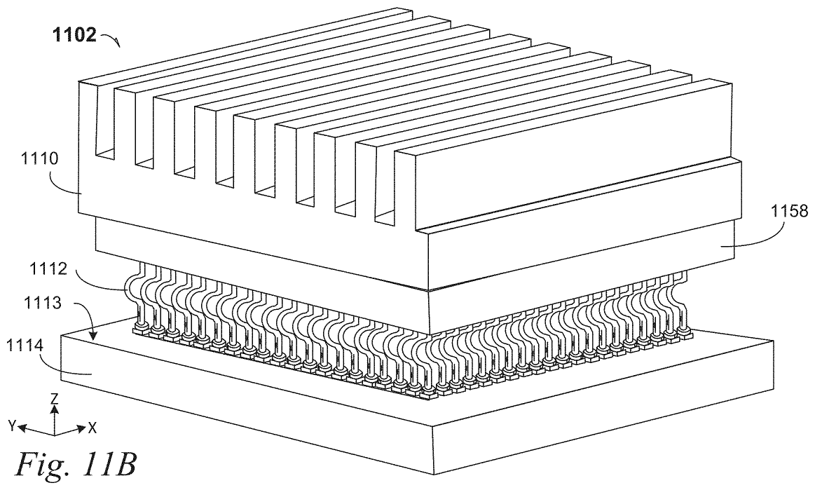

FIG. 11 is a perspective elevation of a composite compliant micro-structure array in an integrated-circuit package 1100 where a micro-structure buckling beam 1112 is configured in an array between a heat-sink base 1110 and an integrated-circuit die 1114 according to an embodiment. The “buckling beam” is indicated at a buckling area where the reference line 1112 touches the structure 1112 and a formerly linear form factor becomes a curvilinear form factor, followed by another linear form factor. In an embodiment, a micro-structure buckling beam 1112 is one in an array of pre-formed, compliant buckling beams. Assembly of the array includes pick-and-place standing the buckling beams 1112 on the backside surface 1113 of the integrated-circuit die 1114.

In an embodiment, a heat-transfer filler such as any of the separate heat-transfer fillers 832 depicted in FIG. 8, is inserted between the backside surface 1113 and the heat-sink base 1110.

FIG. 11A is a perspective elevation detail 1101 of the micro-structure buckling beam 1112 depicted in FIG. 11 according to an embodiment. An etched pedestal 1156 is assembled to a micro-structure buckling beam 1112, such as by a wire-attachment technique, where a collar and fillet bond the micro-structure buckling beam 1112 to the pedestal 1156. For example in FIG. 1B where the reference arrow 113 touches the die 114, a bond wire may extend from the reference arrow location 113 to the die side 119 of the package 118, and active devices and metallization 115 are between the die 114 and the heat-sink base 110, and the package 118 contacts the die 114 in lieu of the illustrate structure 115.

FIG. 11B is a perspective elevation of a composite compliant micro-structure array in an integrated-circuit package 1102, where an energy-storage device that uses a cold block and a heater, are assembled to a composite compliant pillar micro-structure buckling beam array according to an embodiment.

In an embodiment, a micro-structure buckling beam 1112 is one in an array of pre-formed, compliant buckling beams. Assembly of the array includes pick-and-place standing the buckling beams 1112 on the backside surface 1113 of the integrated-circuit die 1114.

A cold block 1110 is assembled to a heater 1158 to provide a thermal capacitive application for regulating heat management of the integrated-circuit die 1114.

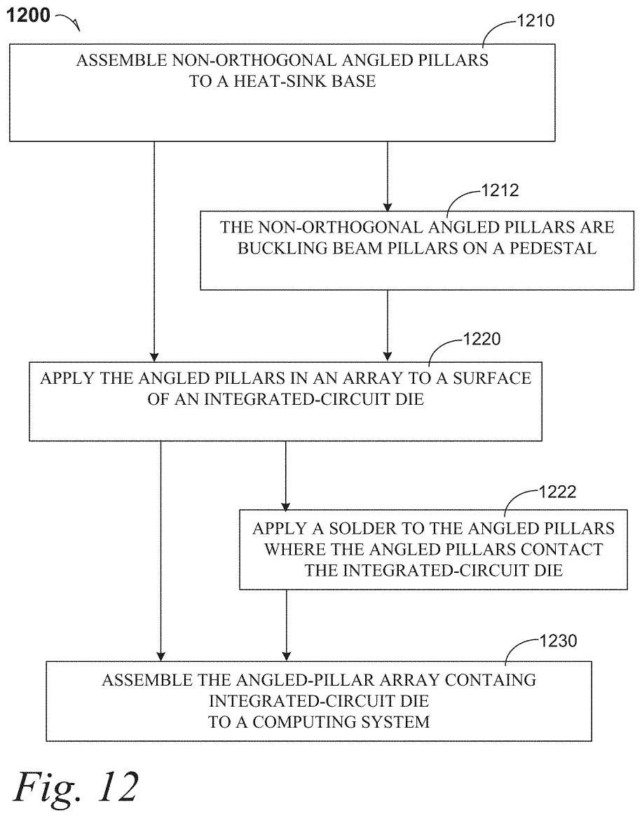

FIG. 12 is a process flow diagram according to several embodiments.

At 1210, the process includes assembling non-orthogonal compliant pillars into an array, to a heat-sink base.

At 1212, the process includes buckling beam pillars where a portion of the pillar is non-orthogonal to the plane of the heat-sink base.

At 1220, the process includes applying the angled pillars in an array to a surface of an integrated-circuit die. In a non-limiting example embodiment, a wire-bond die has the backside surface on the die side of an integrated-circuit package substrate, and the CCP TIM is applied to the active devices and metallization (with a passivation layer on the active surface) and heat is extracted from the active devices and metallization.

At 1222, the process includes applying a solder material where the angled pillars contact the integrated-circuit die.

At 1230, the process includes assembling the angled-pillar array containing integrated-circuit die to a computing system.

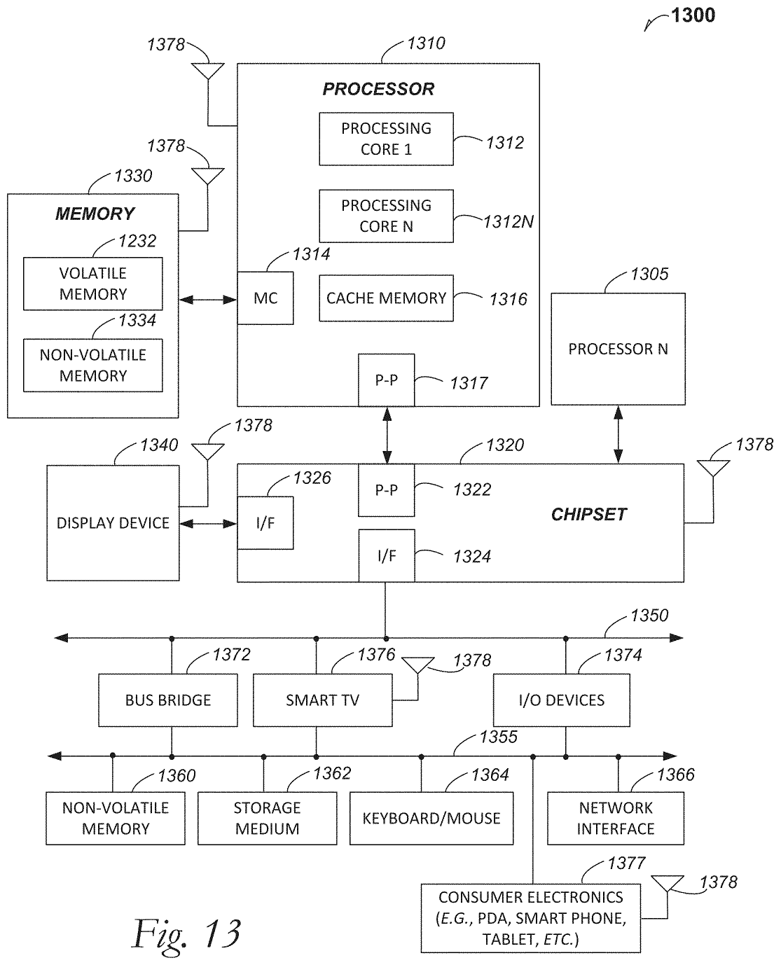

FIG. 13 is included to show an example of a higher-level device application for the disclosed embodiments. The composite compliant pillar micro-structure array embodiments may be found in several parts of a computing system. In an embodiment, the composite compliant pillar micro-structure array embodiments can be part of a communications apparatus such as is affixed to a cellular communications tower. In an embodiment, a computing system 1300 includes, but is not limited to, a desktop computer. In an embodiment, a computing system 1300 includes, but is not limited to a laptop computer. In an embodiment, a computing system 1300 includes, but is not limited to a tablet. In an embodiment, a computing system 1300 includes, but is not limited to a notebook computer. In an embodiment, a computing system 1300 includes, but is not limited to a personal digital assistant (PDA). In an embodiment, a computing system 1300 includes, but is not limited to a server. In an embodiment, a computing system 1300 includes, but is not limited to a workstation. In an embodiment, a computing system 1300 includes, but is not limited to a cellular telephone. In an embodiment, a computing system 1300 includes, but is not limited to a mobile computing device. In an embodiment, a computing system 1300 includes, but is not limited to a smart phone. In an embodiment, a system 1300 includes, but is not limited to an internet appliance. Other types of computing devices may be configured with the microelectronic device that includes composite compliant pillar micro-structure array embodiments.

In an embodiment, the processor 1310 has one or more processing cores 1312 and 1312N, where 1312N represents the Nth processor core inside processor 1310 where N is a positive integer. In an embodiment, the electronic device system 1300 using a composite compliant pillar micro-structure array embodiment that includes multiple processors including 1310 and 1305, where the processor 1305 has logic similar or identical to the logic of the processor 1310. In an embodiment, the processing core 1312 includes, but is not limited to, pre-fetch logic to fetch instructions, decode logic to decode the instructions, execution logic to execute instructions and the like. In an embodiment, the processor 1310 has a cache memory 1316 to cache at least one of instructions and data for the composite compliant pillar micro-structure array element on an integrated-circuit package substrate in the system 1300. The cache memory 1316 may be organized into a hierarchal structure including one or more levels of cache memory.

In an embodiment, the processor 1310 includes a memory controller 1314, which is operable to perform functions that enable the processor 1310 to access and communicate with memory 1330 that includes at least one of a volatile memory 1332 and a non-volatile memory 1334. In an embodiment, the processor 1310 is coupled with memory 1330 and chipset 1320. In an embodiment, the chipset 1320 is part of a composite compliant pillar micro-structure array embodiment depicted in FIG. 1A. The processor 1310 may also be coupled to a wireless antenna 1378 to communicate with any device configured to at least one of transmit and receive wireless signals. In an embodiment, the wireless antenna interface 1378 operates in accordance with, but is not limited to, the IEEE 802.11 standard and its related family, Home Plug AV (HPAV), Ultra Wide Band (UWB), Bluetooth, WiMax, or any form of wireless communication protocol.

In an embodiment, the volatile memory 1332 includes, but is not limited to, Synchronous Dynamic Random-Access Memory (SDRAM), Dynamic Random-Access Memory (DRAM), RAMBUS Dynamic Random-Access Memory (RDRAM), and/or any other type of random access memory device. The non-volatile memory 1334 includes, but is not limited to, flash memory, phase change memory (PCM), read-only memory (ROM), electrically erasable programmable read-only memory (EEPROM), or any other type of non-volatile memory device.

The memory 1330 stores information and instructions to be executed by the processor 1310. In an embodiment, the memory 1330 may also store temporary variables or other intermediate information while the processor 1310 is executing instructions. In the illustrated embodiment, the chipset 1320 connects with processor 1310 via Point-to-Point (PtP or P-P) interfaces 1317 and 1322. Either of these PtP embodiments may be achieved using a composite compliant pillar micro-structure array embodiment as set forth in this disclosure. The chipset 1320 enables the processor 1310 to connect to other elements in a composite compliant pillar micro-structure array embodiment in a system 1300. In an embodiment, interfaces 1317 and 1322 operate in accordance with a PtP communication protocol such as the Intel® QuickPath Interconnect (QPI) or the like. In other embodiments, a different interconnect may be used.

In an embodiment, the chipset 1320 is operable to communicate with the processor 1310, 1305N, the display device 1340, and other devices 1372, 1376, 1374, 1360, 1362, 1364, 1366, 1377, etc. The chipset 1320 may also be coupled to a wireless antenna 1378 to communicate with any device configured to at least do one of transmit and receive wireless signals.

The chipset 1320 connects to the display device 1340 via the interface 1326. The display 1340 may be, for example, a liquid crystal display (LCD), a plasma display, cathode ray tube (CRT) display, or any other form of visual display device. In an embodiment, the processor 1310 and the chipset 1320 are merged into a composite compliant pillar micro-structure array embodiment in a system. Additionally, the chipset 1320 connects to one or more buses 1350 and 1355 that interconnect various elements 1374, 1360, 1362, 1364, and 1366. Buses 1350 and 1355 may be interconnected together via a bus bridge 1372 such as at least one composite compliant pillar micro-structure array embodiment. In an embodiment, the chipset 1320, via interface 1324, couples with a non-volatile memory 1360, a mass storage device(s) 1362, a keyboard/mouse 1364, a network interface 1366, smart TV 1376, and the consumer electronics 1377, etc.

In an embodiment, the mass storage device 1362 includes, but is not limited to, a solid-state drive, a hard disk drive, a universal serial bus flash memory drive, or any other form of computer data storage medium. In one embodiment, the network interface 1366 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 13 are depicted as separate blocks within the composite compliant pillar micro-structure array embodiments in a computing system 1300, the functions performed by some of these blocks may be integrated within a single semiconductor circuit or may be implemented using two or more separate integrated circuits. For example, although cache memory 1316 is depicted as a separate block within processor 1310, cache memory 1316 (or selected aspects of 1316) can be incorporated into the processor core 1312.

To illustrate the composite compliant pillar micro-structure array embodiments and methods disclosed herein, a non-limiting list of examples is provided herein:

Example 1 is a heat-transfer apparatus, comprising: a heat-sink base; an array of pillars that are deployed at an angle that deviates from the orthogonal.

In Example 2, the subject matter of Example 1 optionally includes wherein the array of has packing density that is proportional to more than twice each pillar cross section.

In Example 3, the subject matter of any one or more of Examples 1-2 optionally include an integrated circuit die, wherein at least one pillar of the array of pillars contacts the integrated circuit die on a backside surface, and wherein the at least one pillar is deflected where it contacts the backside surface.

In Example 4, the subject matter of any one or more of Examples 1-3 optionally include a wire-bond integrated circuit die, wherein at least one pillar of the array of pillars contacts the integrated circuit die on active device and metallization surface between wirebonds, and wherein the at least one pillar is deflected where it contacts the active device and metallization.

In Example 5, the subject matter of any one or more of Examples 1-4 optionally include a first integrated circuit die, wherein at least one pillar of the array of pillars contacts first the integrated circuit die on a backside surface, and wherein the at least one pillar is deflected where it contacts the backside surface; and a subsequent integrated circuit die, wherein at least one pillar of the array of pillars contacts subsequent the integrated circuit die on a backside surface, and wherein the at least one pillar is deflected where it contacts the backside surface.

In Example 6, the subject matter of any one or more of Examples 1-5 optionally include a first integrated circuit die including a first height, wherein at least one pillar of the array of pillars contacts first the integrated circuit die on a backside surface, and wherein the at least one pillar is deflected where it contacts the backside surface; a subsequent integrated circuit die including a subsequent height, wherein at least one pillar of the array of pillars contacts subsequent the integrated circuit die on a backside surface, and wherein the at least one pillar is deflected where it contacts the backside surface; and wherein the subsequent height is less than the first height.

In Example 7, the subject matter of any one or more of Examples 1-6 optionally include a first integrated circuit die, wherein at least one pillar of the array of pillars contacts first the integrated circuit die on a backside surface, and wherein the at least one pillar is deflected where it contacts the backside surface; and a subsequent integrated circuit die, that is coupled to the heat-sink base by a bonded thermal interface material that contacts the subsequent the integrated circuit die on a backside surface.

In Example 8, the subject matter of any one or more of Examples 1-7 optionally include an integrated circuit die on a package substrate, wherein at least one pillar of the array of pillars contacts the integrated circuit die on a backside surface, and wherein the at least one pillar is deflected where it contacts the backside surface; and wherein at least on pillar of the array of pillars contacts package substrate on a die side, wherein the package substrate includes a land side opposite the die side.

In Example 9, the subject matter of any one or more of Examples 1-8 optionally include an integrated circuit die, wherein at least one pillar of the array of pillars contacts the integrated circuit die on a metallic solder film on a backside surface of the integrated-circuit die, and wherein the at least one pillar is both wetted by the metallic solder film and is deflected where it contacts the metallic solder film.

In Example 10, the subject matter of any one or more of Examples 1-9 optionally include an integrated circuit die, wherein at least one pillar of the array of pillars contacts the integrated circuit die on a metallic solder tip on the at least one pillar, and wherein the at least one pillar is both wetted by the metallic solder tip and is deflected where it contacts the metallic solder tip.

In Example 11, the subject matter of any one or more of Examples 1-10 optionally include an integrated circuit die, wherein at least one pillar of the array of pillars contacts the integrated circuit die on a backside surface, and wherein the at least one pillar is deflected where it contacts the backside surface; and a heat-transfer filler that permeates the array of pillars between the die backside surface and the heat-sink base, and wherein the heat-transfer filler is selected from the group consisting of thermal grease, a compliant polymer thermal interface material that is more compliant than the array of pillars, an inert gas, a mineral oil, and air.

In Example 12, the subject matter of any one or more of Examples 1-11 optionally include wherein each pillar in the array of pillars has a cross-sectional form factor selected from a circle, an ellipse, a square, an oblique diamond and a rectangle.

In Example 13, the subject matter of any one or more of Examples 1-12 optionally include wherein each pillar of the array of pillars has an elongate form factor selected from the group consisting of a uniform column, a tapered column, a reverse-tapered column, and a buckling beam.

Example 14 is a process of forming a heat-transfer apparatus, comprising: forming an angled array of metallic pillars upon a heat-sink by plating into pillar-form-factor negative spaces through a mask.

In Example 15, the subject matter of Example 14 optionally includes forming a solder tip on each of the pillars.

In Example 16, the subject matter of any one or more of Examples 14-15 optionally include contacting a heat source with at least one of the angled pillars.

Example 17 is a computing system, comprising: an integrated-circuit die; an integrated-circuit package substrate coupled to the integrate-circuit die on a die side; a board coupled to the integrated-circuit package substrate at a land side a heat-sink base; an array of pillars that are deployed at an angle that deviates from the orthogonal of the heat-sink base, wherein at least one pillar of the array of pillars contacts the integrated circuit die on a backside surface, and wherein the at least one pillar is deflected where it contacts the backside surface; and wherein the integrated-circuit die is part of a multi-chip package.

In Example 18, the subject matter of Example 17 optionally includes wherein the multi-chip package is part of a chipset.

In Example 19, the subject matter of any one or more of Examples 17-18 optionally include wherein the integrated-circuit die is a memory die, and wherein the array of pillars is deployed from a heat pipe that contacts a heat spreader; and a central processor that contacts the heat spreader through a metallic thermal-interface material; and wherein the memory die and the central processor are part of a chipset.

In Example 20, the subject matter of any one or more of Examples 17-19 optionally include wherein the integrated-circuit die is a memory die, and wherein the array of pillars is deployed from a heat pipe that contacts a heat spreader; a central processor that contacts the heat spreader through a metallic thermal-interface material; and wherein the memory die and the central processor are part of a chipset; and wherein the board includes an external shell.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second.” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electrical device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the disclosed embodiments should be determined with reference to the appended claims, along with the full scope of equivalents to which such claims are entitled.

1. A heat-transfer apparatus, comprising:
a heat-sink base;
an array of pillars that are deployed at an angle that deviates from the orthogonal.

2. The heat-transfer apparatus of claim 1, wherein the array of has packing density that is proportional to more than twice each pillar cross section.

3. The heat-transfer apparatus of claim 1, further including;
an integrated circuit die, wherein at least one pillar of the array of pillars contacts the integrated circuit die on a backside surface, and wherein the at least one pillar is deflected where it contacts the backside surface.

4. The heat-transfer apparatus of claim 1, further including;
a wire-bond integrated circuit die, wherein at least one pillar of the array of pillars contacts the integrated circuit die on active device and metallization surface between wirebonds, and wherein the at least one pillar is deflected where it contacts the active device and metallization.

5. The heat-transfer apparatus of claim 1, further including;
a first integrated circuit die, wherein at least one pillar of the array of pillars contacts first the integrated circuit die on a backside surface, and wherein the at least one pillar is deflected where it contacts the backside surface; and
a subsequent integrated circuit die, wherein at least one pillar of the array of pillars contacts subsequent the integrated circuit die on a backside surface, and wherein the at least one pillar is deflected where it contacts the backside surface.

6. The heat-transfer apparatus of claim 1, further including;
a first integrated circuit die including a first height, wherein at least one pillar of the array of pillars contacts first the integrated circuit die on a backside surface, and wherein the at least one pillar is deflected where it contacts the backside surface;
a subsequent integrated circuit die including a subsequent height, wherein at least one pillar of the array of pillars contacts subsequent the integrated circuit die on a backside surface, and wherein the at least one pillar is deflected where it contacts the backside surface; and
wherein the subsequent height is less than the first height.

7. The heat-transfer apparatus of claim 1, further including;
a first integrated circuit die, wherein at least one pillar of the array of pillars contacts first the integrated circuit die on a backside surface, and wherein the at least one pillar is deflected where it contacts the backside surface; and
a subsequent integrated circuit die, that is coupled to the heat-sink base by a bonded thermal interface material that contacts the subsequent the integrated circuit die on a backside surface.

8. The heat-transfer apparatus of claim 1, further including;
an integrated circuit die on a package substrate, wherein at least one pillar of the array of pillars contacts the integrated circuit die on a backside surface, and wherein the at least one pillar is deflected where it contacts the backside surface; and
wherein at least on pillar of the array of pillars contacts package substrate on a die side, wherein the package substrate includes a land side opposite the die side.

9. The heat-transfer apparatus of claim 1, further including;
an integrated circuit die, wherein at least one pillar of the array of pillars contacts the integrated circuit die on a metallic solder film on a backside surface of the integrated-circuit die, and wherein the at least one pillar is both wetted by the metallic solder film and is deflected where it contacts the metallic solder film.

10. The heat-transfer apparatus of claim 1, further including;
an integrated circuit die, wherein at least one pillar of the array of pillars contacts the integrated circuit die on a metallic solder tip on the at least one pillar, and wherein the at least one pillar is both wetted by the metallic solder tip and is deflected where it contacts the metallic solder tip.

11. The heat-transfer apparatus of claim 1, further including;
an integrated circuit die, wherein at least one pillar of the array of pillars contacts the integrated circuit die on a backside surface, and wherein the at least one pillar is deflected where it contacts the backside surface; and
a heat-transfer filler that permeates the array of pillars between the die backside surface and the heat-sink base, and wherein the heat-transfer filler is selected from the group consisting of thermal grease, a compliant polymer thermal interface material that is more compliant than the array of pillars, an inert gas, a mineral oil, and air.

12. The heat-transfer apparatus of claim 1, wherein each pillar in the array of pillars has a cross-sectional form factor selected from a circle, an ellipse, a square, an oblique diamond and a rectangle.

13. The heat-transfer apparatus of claim 1, wherein each pillar of the array of pillars has an elongate form factor selected from the group consisting of a uniform column, a tapered column, a reverse-tapered column, and a buckling beam.

14. A process of forming a heat-transfer apparatus, comprising:
forming an angled array of metallic pillars upon a heat-sink by plating into pillar-form-factor negative spaces through a mask.

15. The process of claim 14, further including forming a solder tip on each of the pillars.

16. The process of claim 14, further including contacting a heat source with at least one of the angled pillars.

17. A computing system, comprising:
an integrated-circuit die;
an integrated-circuit package substrate coupled to the integrate-circuit die on a die side;
a board coupled to the integrated-circuit package substrate at a land side
a heat-sink base;
an array of pillars that are deployed at an angle that deviates from the orthogonal of the heat-sink base, wherein at least one pillar of the array of pillars contacts the integrated circuit die on a backside surface, and wherein the at least one pillar is deflected where it contacts the backside surface; and
wherein the integrated-circuit die is part of a multi-chip package.

18. The computing system of claim 17, wherein the multi-chip package is part of a chipset.

19. The computing system of claim 17, wherein the integrated-circuit die is a memory die, and wherein the array of pillars is deployed from a heat pipe that contacts a heat spreader; and
a central processor that contacts the heat spreader through a metallic thermal-interface material; and wherein the memory die and the central processor are part of a chipset.

20. The computing system of claim 17, wherein the integrated-circuit die is a memory die, and wherein the array of pillars is deployed from a heat pipe that contacts a heat spreader;
a central processor that contacts the heat spreader through a metallic thermal-interface material; and wherein the memory die and the central processor are part of a chipset; and
wherein the board includes an external shell.
